(19) United States
(12) Patent Application Publication
(10) Pub. No.: US 2026/0185229 A1
(43) Pub. Date: Jul. 2, 2026

(54) Methods and Systems for Gas Injection

(71) Applicant: Applied Materials, Inc., Santa Clara, CA (US)

(72) Inventors: Udit KOTAGI, Singapore (SG); Zongbin WANG, Singapore (SG); Ganesh BALASUBRAMANIAN, Bengaluru (IN); Mayur Govind KULKARNI, Bangalore (IN); Sandesh HEMADRI, Bengaluru (IN); Anish JANAKIRAMAN, Bengaluru (IN); Anirudh ALEWOOR, Bangalore (IN); Bernard Christy PIUS, Bengaluru (IN); Rohit BANSAL, Bengaluru (IN); Vijay GOLE, Bengaluru (IN)

(21) Appl. No.: 19/002,891

(22) Filed: Dec. 27, 2024

(51) Int. Cl. C23C 16/455; C23C 16/40

(52) U.S. Cl. CPC C23C 16/45561; C23C 16/402

(57) ABSTRACT

A system for gas injection includes: a first three-port valve having a first port connectable to a substrate processing chamber, a second port connected to a supply of a first gas, and a third port; and a second three-port valve having a first port connected to a supply of a second gas, a second port connected to the third port of the first three-port valve, and a third port connectable to a divert path, wherein in a first configuration, the first three-port valve and the second three-port valve are configured to route the first gas and the second gas to exit the first port of the first three-port valve, wherein in a second configuration, the first three-port valve and the second three-port valve are configured to route the first gas and the second gas to exit the third port of the second three-port valve.

### FIELD

Embodiments of the present disclosure generally relate to methods and systems for fluid injection for substrate processing chambers, and more specifically, to methods and systems for injection of tetra-ethyl-ortho-silicate (TEOS).

### BACKGROUND

Tetra-ethyl-ortho-silicate (TEOS) vapor is used in chemical vapor deposition (CVD) processes for deposition of silicon oxide films on semiconductor substrates. TEOS is a liquid at room temperature. TEOS slowly hydrolyzes into silicon dioxide and ethanol when in contact with ambient moisture.

A liquid injection system may be used to produce the TEOS vapor for use in substrate processing chambers. Temperatures above room temperature may be used to increase the TEOS partial pressure, which may require heating the gas lines carrying the TEOS to prevent condensation therein. The TEOS condensation introduced into the substrate processing chamber can undesirably cause defects in films deposited on substrates in the substrate processing chamber.

For TEOS liquid injection systems, TEOS delivered to the chamber is typically stabilized and does not include accumulated moisture or other contaminants that may be present in dead volumes of piping, such as in valves and manifolds upstream of the substrate processing chamber. One attempt to reduce condensation contamination and stabilize the TEOS flow is to flow vaporized TEOS along a divert path that bypasses the substrate processing chamber prior to switching or otherwise rerouting the TEOS flow into the substrate processing chamber. Nevertheless, dead volumes remain due to piping configuration and manufacturing constraints. Diffusion can make TEOS trapped in the dead volumes difficult to remove without repeated or cyclic flowing TEOS between the chamber and the divert path, which can increase processing times and thereby reduce throughput of the substrate processing chamber. Even with switching or cycling TEOS flow between the divert path and the chamber, there is a possibility of contamination from condensation of the TEOS in dead volumes of piping.

Thus, methods and apparatus are proposed that can reduce or eliminate dead volumes and contamination in TEOS injection.

### SUMMARY

Methods and apparatus for injecting gas are provided herein. In some embodiments, a system for gas injection includes: a first three-port valve having a first port connectable to a substrate processing chamber, a second port connected to a supply of a first gas, and a third port; and a second three-port valve having a first port connected to a supply of a second gas, a second port connected to the third port of the first three-port valve, and a third port connectable to a divert path that bypasses flow of the second gas to the first three-port valve, wherein the system is configurable between a first configuration and a second configuration, wherein in the first configuration, the first three-port valve and the second three-port valve are configured to route the first gas and the second gas to exit the first port of the first three-port valve while bypassing the third port of the second three-port valve, wherein in the second configuration, the first three-port valve and the second three-port valve are configured to route the first gas and the second gas to exit the third port of the second three-port valve while bypassing the first port of the first three-port valve, and wherein there is no dead volume between the third port of the first three-port valve and the second port of the second three-port valve in the first configuration and the second configuration.

In some embodiments, a method for injecting a gas into a substrate processing chamber includes: configuring a system for gas injection between a first configuration and a second configuration, wherein the system for gas injection includes: a first three-port valve having a first port connected to a substrate processing chamber, a second port connected to a supply of a first gas, and a third port; and a second three-port valve having a first port connected to a supply of a second gas, a second port connected to the third port of the first three-port valve, and a third port connected to a divert path that bypasses flow of the second gas to the first three-port valve, wherein the system is configurable between a first configuration and a second configuration, wherein in the first configuration, the first three-port valve and the second three-port valve are configured to route the first gas and the second gas to exit the first port of the first three-port valve while bypassing the third port of the second three-port valve, and in the second configuration, the first three-port valve and the second three-port valve are configured to route the first gas and the second gas to exit the third port of the second three-port valve while bypassing the first port of the first three-port valve, and wherein there is no dead volume between the third port of the first three-port valve and the second port of the second three-port valve in the first configuration and the second configuration.

In some embodiments, a system for substrate processing includes: a substrate processing chamber; and a system for gas injection coupled to the substrate processing chamber, the system for gas injection comprising: a first three-port valve having a first port connected to the substrate processing chamber. a second port connected to a supply of a first gas, and a third port; and a second three-port valve having a first port connected to a supply of a second gas, a second port connected to a divert path that bypasses flow to the substrate processing chamber, and a third port connected to the third port of the first three-port valve, wherein the system is configurable between a first configuration and a second configuration, wherein in the first configuration, the first three-port valve and the second three-port valve are configured to route the first gas and the second gas to exit the first port of the first three-port valve while bypassing the third port of the second three-port valve, wherein in the second configuration, the first three-port valve and the second three-port valve are configured to route the first gas and the second gas to exit the third port of the second three-port valve while bypassing the first port of the first three-port valve, and wherein there is no dead volume between the third port of the first three-port valve and the second port of the second three-port valve in the first configuration and the second configuration.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a method for injecting a gas in accordance with some embodiments of the present disclosure.

FIG. 2 shows, schematically, a gas injection system in a first configuration in accordance with some embodiments of the present disclosure.

FIG. 3 shows the gas injection system of FIG. 2 in a second configuration in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and systems for gas injection in substrate chambers are provided herein. As described more fully below, the methods and systems allow for switching a flow of a gas between two paths without trapping the gas in a dead volume when the flow is switched. The two paths include a path flowing to a substrate processing chamber and a path flowing to a divert path that bypasses the substrate processing chamber. Where the gas includes TEOS, the lack of a dead or trapped volume can eliminate contamination caused by TEOS remnants (e.g., TEOS condensation) entering the substrate processing chamber when the flow of gas is switched from the divert path to the substrate processing chamber. As a result, defects caused by contamination may be reduced and substrate processing throughput may be increased.

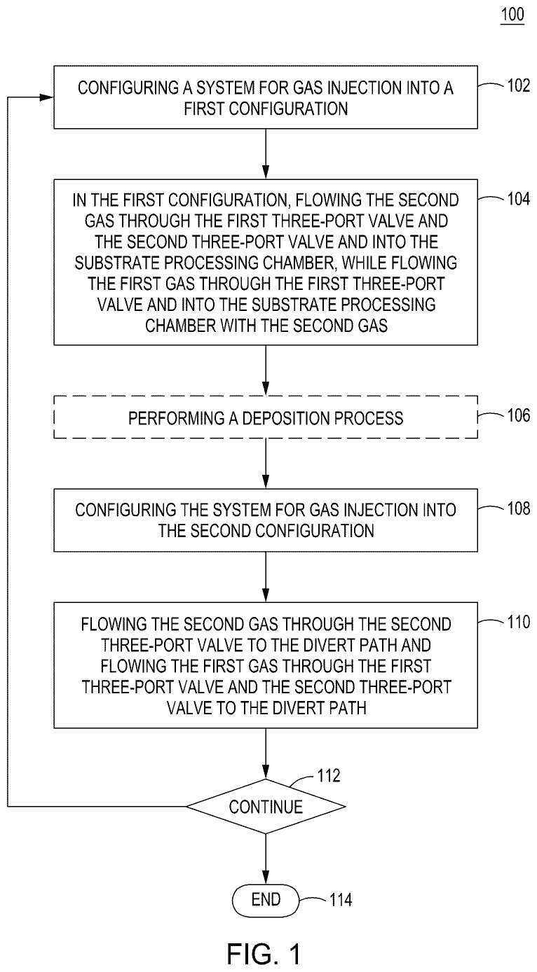

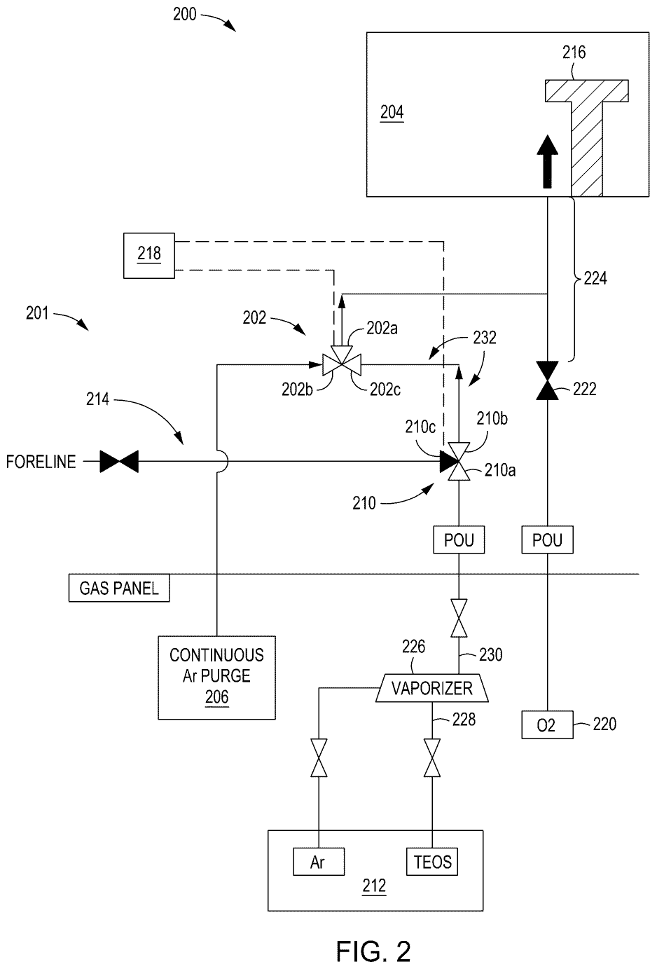

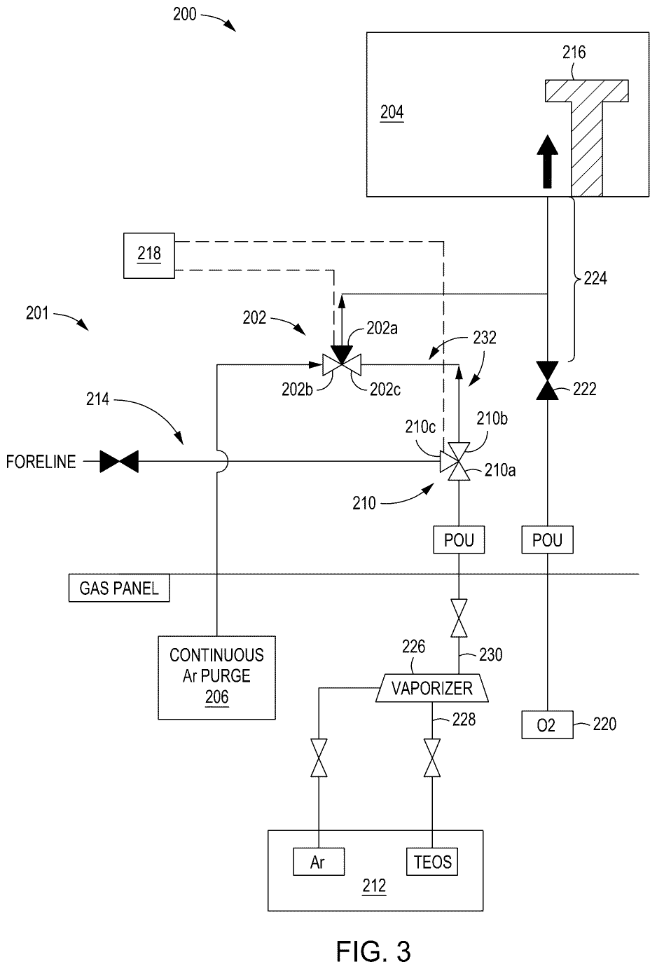

FIG. 1 shows a method 100 for injecting a gas into a substrate processing chamber according to some embodiments of the present disclosure. The method includes configuring a system for gas injection between a first configuration and a second configuration. At block 102, the method 100 includes configuring a system for gas injection into the first configuration. FIG. 2 shows a system for substrate processing 200 that includes a substrate processing chamber 204 and a system for gas injection 201 coupled to the substrate processing chamber 204. In some embodiments and as shown in FIG. 2, the system for gas injection 201 includes a first three-port valve 202 having a first port 202a connectable to a substrate processing chamber 204, a second port 202b connected to a supply of a first gas 206, and a third port 202c. In FIG. 2, the first port 202a of the first three-port valve 202 is shown connected to the substrate processing chamber 204. The system for gas injection 201 also includes a second three-port valve 210 having a first port 210a connected to a supply of a second gas 212, a second port 210b connected to the third port 202c of the first three-port valve 202, and a third port 210c connected to a divert path 214 in the foreline that bypasses flow of the second gas to the first three-port valve 202. The system for gas injection 201 is configurable between the first configuration and the second configuration, which is shown in FIG. 3 and discussed further below.

In the first configuration, the first three-port valve 202 and the second three-port valve 210 are configured to route the first gas and the second gas to exit the first port 202a of the first three-port valve while bypassing the third port 210c of the second three-port valve 210. In the first configuration, the third port 210c of the second three-port valve 210 is closed and the first port 202a, the second port 202b, and the third port 202c of the first three-port valve 202 are open, and the first port 210a and the second port 210b of the second three-port valve 210 are open.

At block 104, the method 100 includes flowing the second gas through the first three-port valve 202 and the second three-port valve 210 and into the substrate processing chamber 204, while flowing the first gas through the first three-port valve 202 and into the substrate processing chamber 204 with the second gas. In embodiments, and as shown in FIGS. 2 and 3, the supply of the first gas 206 includes a supply of argon or other inert gas and/or noble gas. In embodiments, and as shown in FIGS. 2 and 3, the supply of the second gas 212 includes a supply of at least one of TEOS or argon.

In some embodiments, and as shown in FIGS. 2 and 3, the substrate processing chamber 204 may be a deposition chamber that includes a substrate support 216 for supporting a substrate during a deposition process. In some embodiments, the substrate processing chamber 204 is a CVD chamber. Optionally at block 106, the method 100 may include performing a deposition process in the substrate processing chamber 204 while flowing the first gas and the second gas into the substrate processing chamber 204.

In some embodiments, and as shown in FIGS. 2 and 3, the supply of the second gas 212 may include a source of liquid TEOS and a vaporizer 226 having an inlet 228 coupled to the source of liquid TEOS, and an outlet 230 coupled to the first port 210a of the second three-port valve 210.

At block 108, the method 100 may include configuring the system for gas injection 201 into the second configuration, shown in FIG. 3. At block 110, the method 100 may include flowing the second gas through the second three-port valve 210 to the divert path 214 and flowing the first gas through the first three-port valve 202 and the second three-port valve 210 to the divert path 214. In the second configuration, the first three-port valve 202 and the second three-port valve 210 are configured to route the first gas and the second gas to exit the third port 210c of the second three-port valve 210 while bypassing the first port 202a of the first three-port valve 202. In some embodiments, and as shown in FIG. 3, in the second configuration, the first port 202a of the first three-port valve 202 is closed and the first port 210a, the second port 210b, and the third port 210c of the second three-port valve 210 are open, and the second port 202b and the third port 202c of the first three-port valve 202 are open. In embodiments, the first gas remains flowing through the first three-port valve 202 between the first configuration and the second configuration.

As shown in FIG. 2, in the first configuration, a volume of piping 232 between the second port 210b of the second three-port valve 210 and the third port 202c of the first three-port valve 202 routes a flow of the second gas and is not a dead volume. Also, as shown in FIG. 3, in the second configuration, the volume of piping 232 routes a flow of the first gas to the divert path and is not a dead or trapped volume of gas. Thus, in both the first configuration or the second configuration, there is no trapped volume or dead volume between the first three-port valve 202 and the second three-port valve 210 which could contain a trapped amount of the second gas. Where the second gas includes TEOS, the TEOS cannot be trapped in a dead volume between the first three-port valve 202 and the second three-port valve 210 which could lead to possible condensation and contamination of TEOS discussed above. As a result, when the system for gas injection 201 is reconfigured from the second configuration to the first configuration to flow TEOS to the substrate processing chamber 204, there will be no TEOS remnants in the volume between the first three-port valve 202 and the second three-port valve 210, thereby eliminating potential contamination (i.e., condensed TEOS) entering the substrate processing chamber 204 and allowing for more rapid stabilization of TEOS flow in the substrate processing chamber 204.

In practice, switching between the first configuration and the second configuration may alternate or cycle based on substrate processing in the substrate processing chamber 204. For example, before performing a deposition process in the substrate processing chamber 204, the system for gas injection 201 may be initially configured in the second configuration to stabilize the flow of the first gas and the second gas. Then, when deposition processing is desired to begin, the system for gas injection 201 may be reconfigured into the first configuration to flow the first gas and the second gas into the substrate processing chamber 204. Also, when deposition processing ends, the system for gas injection 201 may be reconfigured into the second configuration while, for example, other substrate processing is occurring in the substrate processing chamber or when the processed substrate is swapped for another substrate to be processed. At block 112, the method 100 may include determining whether to continue or end substrate processing. If yes at block 112, the method 100 returns to block 102. Otherwise, if no at block 112, the method 100 ends at block 114 at which time the flow of the first gas and the second gas may stop.

The configuration of the system for gas injection 201 between the first configuration and the second configuration may be accomplished by reconfiguring the first three-port valve 202 and the second three-port valve 210 as described above. In some embodiments, at least one of the first three-port valve 202 or the second three-port valve 210 may be remotely controlled. In some embodiments, at least one of the first three-port valve 202 or the second three-port valve 210 is pneumatically actuated or electrically actuated. In some embodiments, at least one of the first three-port valve 202 or the second three-port valve 210 may be communicatively coupled to a controller 218 (e.g., a computer) configured to remotely control and actuate at least one of the first three-port valve 202 or the second three-port valve 210.

In some embodiments, and as shown in FIGS. 2 and 3, a supply of a third gas 220 may be connected to the substrate processing chamber 204. The third gas may include oxygen. An isolation valve 222 may be connected between the substrate processing chamber 204 and the supply of the third gas 220. In some embodiments, when the system for gas injection 201 is in the first configuration, the isolation valve 222 may be opened so that the third gas may flow into the substrate processing chamber 204 along with the first gas and the second gas. In some embodiments, when the system for gas injection 201 is in the second configuration, the isolation valve 222 may be closed to stop the flow of the third gas to the substrate processing chamber 204. In the second configuration, any remnants of the first gas, the second gas, or the third gas within a no-flow volume 224 defined between the third port 202c of the first three-port valve 202, the substrate processing chamber 204, and the isolation valve 222 is evacuated into the substrate processing chamber 204. As a result, when reconfiguring the system for gas injection 201 from the second configuration to the first configuration, at least the first gas (e.g., argon) and the second gas (e.g., TEOS) will not be present in the no-flow volume 224, which could introduce contamination into the substrate processing chamber 204.

The methods and systems described herein allow for switching a flow of a gas between a path flowing to a substrate processing chamber and a path flowing to a divert path that bypasses the substrate processing chamber. Where the gas includes TEOS, the lack of a dead or trapped volume can eliminate contamination caused by TEOS remnants (e.g., TEOS condensation) entering the substrate processing chamber when the flow of gas is switched from the divert path to the substrate processing chamber. As a result, defects caused by contamination may be reduced and substrate processing throughput may be increased.

While the foregoing is directed to embodiments of the present disclosure, other and further embodiments of the disclosure may be devised without departing from the basic scope thereof.

1. A system for gas injection, the system comprising:
a first three-port valve having a first port connectable to a substrate processing chamber, a second port connected to a supply of a first gas, and a third port; and
a second three-port valve having a first port connected to a supply of a second gas, a second port connected to the third port of the first three-port valve, and a third port connectable to a divert path that bypasses flow of the second gas to the first three-port valve,
wherein the system is configurable between a first configuration and a second configuration, wherein in the first configuration, the first three-port valve and the second three-port valve are configured to route the first gas and the second gas to exit the first port of the first three-port valve while bypassing the third port of the second three-port valve, wherein in the second configuration, the first three-port valve and the second three-port valve are configured to route the first gas and the second gas to exit the third port of the second three-port valve while bypassing the first port of the first three-port valve, and
wherein there is no dead volume between the third port of the first three-port valve and the second port of the second three-port valve in the first configuration and the second configuration.

2. The system of claim 1, wherein in the first configuration the third port of the second three-port valve is closed and the first port, the second port, and the third port of the first three-port valve are open, and the first port and the second port of the second three-port valve are open, and
wherein in the second configuration the first port of the first three-port valve is closed and the first port, second port, and third port of the second three-port valve are open, and the second port and the third port of the first three-port valve are open.

3. The system of claim 1, further wherein the supply of the second gas comprises a supply of at least one of TEOS or argon.

4. The system of claim 3, wherein the supply of the second gas includes a source of liquid TEOS and a vaporizer having an inlet coupled to the source of liquid TEOS, the vaporizer having an outlet coupled to the first port of the second three-port valve.

5. The system of claim 4, wherein the supply of the first gas comprises a supply of argon.

6. The system of claim 1, wherein at least one of the first three-port valve or the second three-port valve are remotely controlled.

7. The system of claim 6, wherein at least one of the first three-port valve or the second three-port valve are pneumatically actuated or electrically actuated.

8. A method for injecting a gas into a substrate processing chamber, the method comprising:
configuring a system for gas injection between a first configuration and a second configuration, wherein the system for gas injection includes:
a first three-port valve having a first port connected to a substrate processing chamber, a second port connected to a supply of a first gas, and a third port; and
a second three-port valve having a first port connected to a supply of a second gas, a second port connected to the third port of the first three-port valve, and a third port connected to a divert path that bypasses flow of the second gas to the first three-port valve,
wherein the system is configurable between a first configuration and a second configuration,
wherein in the first configuration, the first three-port valve and the second three-port valve are configured to route the first gas and the second gas to exit the first port of the first three-port valve while bypassing the third port of the second three-port valve, and in the second configuration, the first three-port valve and the second three-port valve are configured to route the first gas and the second gas to exit the third port of the second three-port valve while bypassing the first port of the first three-port valve, and
wherein there is no dead volume between the third port of the first three-port valve and the second port of the second three-port valve in the first configuration and the second configuration.

9. The method of claim 8, wherein in the first configuration the third port of the second three-port valve is closed and the first port, the second port, and the third port of the first three-port valve are open, and the first port and the second port of the second three-port valve are open.

10. The method of claim 8, wherein the second gas includes at least one of TEOS or argon.

11. The method of claim 8, wherein the first gas includes argon.

12. The method of claim 8, wherein the substrate processing chamber is a CVD chamber and the method further comprises performing a deposition process in the CVD chamber while flowing the first gas and the second gas.

13. The method of claim 8, further comprising:
in the first configuration, flowing the second gas through the first three-port valve and the second three-port valve and into the substrate processing chamber, while flowing the first gas through the first three-port valve and into the substrate processing chamber with the second gas.

14. The method of claim 13, wherein in the second configuration the first port of the first three-port valve is closed and the first port, the second port, and the third port of the second three-port valve are open, and the second port and the third port of the first three-port valve are open.

15. The method of claim 14, wherein the first gas remains flowing through the first three-port valve between the first configuration and the second configuration.

16. A system for substrate processing, the system comprising:
a substrate processing chamber; and
a system for gas injection coupled to the substrate processing chamber, the system for gas injection comprising:
a first three-port valve having a first port connected to the substrate processing chamber, a second port connected to a supply of a first gas, and a third port; and
a second three-port valve having a first port connected to a supply of a second gas, a second port connected to a divert path that bypasses flow to the substrate processing chamber, and a third port connected to the third port of the first three-port valve,
wherein the system is configurable between a first configuration and a second configuration,
wherein in the first configuration, the first three-port valve and the second three-port valve are configured to route the first gas and the second gas to exit the first port of the first three-port valve while bypassing the third port of the second three-port valve, wherein in the second configuration, the first three-port valve and the second three-port valve are configured to route the first gas and the second gas to exit the third port of the second three-port valve while bypassing the first port of the first three-port valve, and
wherein there is no dead volume between the third port of the first three-port valve and the second port of the second three-port valve in the first configuration and the second configuration.

17. The system of claim 16, wherein in the first configuration the third port of the second three-port valve is closed and the first port, the second port, and the third port of the first three-port valve are open, and the first port and the second port of the second three-port valve are open, and wherein in the second configuration the first port of the first three-port valve is closed and the first port, the second port, and the third port of the second three-port valve are open, and the second port and the third port of the first three-port valve are open.

18. The system according to claim 16, wherein the substrate processing chamber is a deposition chamber that includes a substrate support for supporting a substrate during a deposition process.

19. The system according to claim 18, wherein the supply of the first gas includes a supply of argon.

20. The system according to claim 18, wherein the supply of the second gas includes a supply of at least one of TEOS or argon.
